(19) United States
(12) Patent Application Publication
(10) Pub. No.: US 2017/0140956 A1
(43) Pub. Date: May 18, 2017

(54) Single Piece Ceramic Platen

(71) Applicant: Varian Semiconductor Equipment Associates, Inc., Gloucester, MA (US)

(72) Inventors: Adam M. McLaughlin, Merrimac, MA (US); Jordan B. Tye, Arlington, MA (US)

(21) Appl. No.: 14/940,214

(22) Filed: Nov. 13, 2015

(51) Int. Cl. H01L 21/67; B28B 1/00; B28B 23/00; H01L 21/683

(52) U.S. Cl. CPC H01L 21/67103; H01L 21/6833; B28B 1/001; B28B 23/00; B33Y 10/00

(57) ABSTRACT

A single piece ceramic platen is disclosed. This platen may be manufactured using additive manufacturing. The single piece ceramic platen may be manufactured using additive manufacturing processes. As such, the single piece ceramic platen may include a plurality of embedded features. Electrodes, cooling channels, heating elements, temperature sensors, strain gauges and back side gas channels may each be embedded in the electrode. Incorporation of cooling channels and heating elements allows the platen to operate over a wider range of temperatures. Further, these features may be disposed on a plurality of different depths following a planar or non-planar pathway. For example, the heating elements may be configured such that heating element in one region of the platen, such as an outer edge, are disposed closer to the top surface of the platen.

Embodiments of the present disclosure relate to a single piece ceramic platen, and more particularly, a single piece ceramic platen having integrated heating elements, electrodes, cooling channels and other features.

### BACKGROUND

A semiconductor workpiece is typically processed by disposing the workpiece on a ceramic platen. The ceramic platen has embedded electrodes, which are used to provide an electrostatic force to clamp the workpiece to the platen. In addition, in certain embodiments, the ceramic platen may have cooling channels in order to maintain the platen at a certain temperature, typically at or below room temperature. In certain embodiments, the ceramic platen may have integrated heating elements to maintain the platen at a predetermined elevated temperature. Further, in certain embodiments, the ceramic platen may also include backside gas channels, which allow a gas to be delivered to the volume between the platen and the workpiece.

Traditionally, ceramic platens are constructed using a plurality of manufacturing processes. For example, to embed electrodes within the platen, the platen is typically manufactured using two or more pieces of ceramic material. The bottom piece is etched or otherwise processed to allow conductive electrodes to be disposed on the top surface of this bottom piece. After the electrodes are added to the bottom piece, the top piece of ceramic material is then bonded to the bottom piece, sandwiching the electrodes within the platen.

Similarly, cooling channels are typically created by machining the top surface of the bottom piece of ceramic material, or the bottom surface of the top piece of ceramic material, to create the desired channels. The top piece of ceramic material is then bonded to the bottom piece of ceramic material.

The complexity of having multiple pieces of ceramic material makes the manufacture of these ceramic platens very difficult. Channels for both cooling and electrical conductors are also limited in complexity to two dimensional planes between ceramics pieces. In fact, there are few manufacturers that are capable of creating these complex ceramic platens. In addition, due to the complexity of this manufacturing process, different platens are created for different operating temperatures. For example, one platen may be created with embedded electrodes and cooling channels for room temperature or cold implants. A second platen may be created with embedded electrodes and embedded heating elements for implants at elevated temperatures. The complexity of manufacturing makes it difficult to incorporate all of these elements into one ceramic platen.

Therefore, it would be beneficial if there was a single piece ceramic platen that could incorporate embedded electrodes, heating elements and/or cooling channels. Further, it would be advantageous if the single piece ceramic platen also included other elements, such as temperature sensors and strain gauges. Furthermore, a single piece ceramic may be more structurally sound than conventional ceramic platens, which sinter multiple ceramic pieces together.

### SUMMARY

A single piece ceramic platen is disclosed. This single piece ceramic platen may be manufactured using additive manufacturing processes. As such, the single piece ceramic platen may include a plurality of embedded features. Electrodes, cooling channels, heating elements, temperature sensors, strain gauges and back side gas channels may each be embedded in the electrode. Incorporation of both cooling channels and heating elements into a platen allows the platen to operate over a wider range of temperatures. Further, these features may be disposed at a plurality of different depths following a planar or non-planar pathway within the platen. For example, the heating elements may be configured such that heating elements in one region of the platen, such as an outer edge, are disposed closer to the top surface of the platen than heating elements in another region of the platen.

According to one embodiment, a platen is disclosed. The platen comprises a ceramic material; a heating element embedded within the ceramic material; and cooling channels passing through the ceramic material. In certain embodiments, the platen further comprises electrodes embedded within the ceramic material. In certain embodiments, the platen further comprises a temperature sensor embedded in the ceramic material. In certain embodiments, the heating element and the cooling channels are interweaved. In certain embodiments, the heating element is disposed at a plurality of depths following a planar or non-planar pathway within the ceramic material. In certain embodiments, the cooling channels are disposed at a plurality of depths following a planar or non-planar pathway within the ceramic material.

According to another embodiment, a platen comprising a ceramic material and heating elements embedded within the ceramic material, wherein the heating elements are disposed at a plurality of different depths following a planar or non-planar pathway within the ceramic material, is disclosed. In certain embodiments, the heating elements near an outer edge of the platen are disposed closer to a top surface than heating elements near a center of the platen. In some embodiments, a cross-section area of the heating elements varies within the ceramic material. In some embodiments, a cross-section shape of the heating elements varies within the ceramic material. In certain embodiments, electrodes, a temperature sensor or a strain gauge may also be embedded in the ceramic material.

According to another embodiment, a platen comprising a ceramic material and cooling channels embedded within the ceramic material, wherein the cooling channels are disposed at a plurality of different depths following a planar or non-planar pathway within the ceramic material, is disclosed. In certain embodiments, cooling channels near an outer edge of the platen are disposed closer to a top surface of the platen than cooling channels near a center of the platen. In certain embodiments, cooling channels near an outer edge of the platen are disposed further from a top surface than cooling channels near a center of the platen. In certain embodiments, electrodes, a temperature sensor or a strain gauge may also be embedded in the ceramic material.

### BRIEF DESCRIPTION OF THE FIGURES

For a better understanding of the present disclosure, reference is made to the accompanying drawings, which are incorporated herein by reference and in which:

FIG. 1 shows a flowchart illustrating a process to introduce channels into the ceramic platen using an additive process;

FIG. 2A shows a flowchart illustrating a process to introduce a second material into the ceramic platen according to one embodiment;

FIG. 2B shows a flowchart illustrating a process to introduce a second material into the ceramic platen according to a second embodiment;

FIG. 3A shows a top view of a ceramic platen with embedded electrodes;

FIG. 3B shows a side view of the ceramic platen of FIG. 3A according to one embodiment;

FIG. 3C shows a side view of the ceramic platen of FIG. 3A according to a second embodiment;

FIG. 4 shows a side view of a ceramic platen showing various features that may be embedded therein;

FIG. 5A shows a first view of a ceramic platen with heating elements and cooling channels;

FIG. 5B shows a side view of the ceramic platen of FIG. 5A; and

FIGS. 6A-6D show various surface finishes that may be applied to the ceramic platen.

### DETAILED DESCRIPTION

As described above, ceramic platens are typically manufactured by bonding multiple pieces of ceramic material together. This technique is used to embed electrodes, heating elements or cooling channels within the ceramic platen. However, as described above, there are limitations to this approach. For example, these features are typically embedded in a horizontal plane formed between adjacent ceramic pieces that are stacked on top of one another.

The present disclosure describes a single piece ceramic platen that may be created using additive manufacturing, such as 3D printing or a similar technology. In additive manufacturing, to create a specific shape, material is deposited in exact positions. By repeating this process, layers are created one on top of the other, and a three dimensional object of an arbitrary shape may be created. In the case of ceramic materials, a mixture of ceramic powder and a binding agent may be deposited. This is known as the “green body” state. Once the desired object has been printed, the object is placed in a furnace, where it is sintered. The heat and pressure cause the binding agent to interact with the ceramic powder to bind the ceramic powder together to create the desired ceramic object.

A single piece ceramic platen for use with semiconductor processing may have various elements embedded within the ceramic material. These elements may be grouped broadly into two categories. The first category may be referred to as void regions or channels. These are regions within the ceramic material where there is no material. These regions may be used, for example, for cooling channels, where a cooling fluid is passed through the hollow channels, or back side gas channels. The second category may be referred to as replacement regions. These are regions where the ceramic material is replaced by a different material, such as a conductive material. These replacement regions may be used to create embedded electrodes and heating elements, for example.

By incorporating these two categories of elements into the ceramic material, a single piece ceramic platen having various features may be created. For example, the single piece ceramic platen may include embedded electrodes, cooling channels, heating elements, temperature sensors, strain gauges and other features.

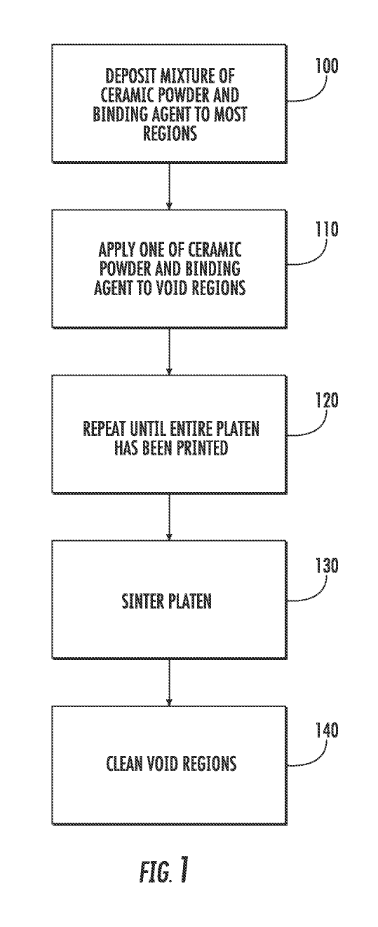

FIG. 1 shows a flowchart that may be used to create void regions or channels. As shown in Process 100, a mixture of ceramic powder and binding agent is deposited, using additive manufacturing, in most regions, as this mixture creates the single piece ceramic platen after sintering. In those regions which are to be left void or empty, only one of the ceramic powder and the binding agent is deposited, as shown in Process 110. The deposition of material is used to maintain the integrity of the platen during the additive manufacturing process. However, since only one of the ceramic powder and the binding agent is deposited, this region will not become hardened after sintering. The deposition process is repeated for each layer until the entire platen has been printed, as shown in Process 120. After all of the material needed to form the platen has been deposited, the platen is placed in a furnace, where the platen is sintered, as shown in Process 130. After sintering, most of the platen has become hardened ceramic. However, the void regions do not become hardened. In the embodiment where only ceramic powder is deposited in the void regions, the ceramic powder may remain in powder form after sintering. In this embodiment, the void region may need to be cleaned, as shown in Process 140. This may be achieved by introducing pressurized air or another fluid in the void regions to clean the void regions. In another embodiment, a vacuum may be applied to the void regions to draw the powder from the void regions. It is noted that, in these embodiments, the void region may have at least one inlet or outlet along the exterior of the ceramic object to facilitate the cleaning process. In the embodiment where only binding agent is deposited in the void regions, the binding agent may evaporate during the sintering process, leaving air gaps in the ceramic platen. In this embodiment, the cleaning process (Process 140) may not be performed.

The sequence shown in FIG. 1 may be used to create cooling channels in the single piece ceramic platen. Typically, the cooling channels are embedded in the platen with at least two external ports; an inlet through which the cooling fluid enters the cooling channels and an outlet through which the cooling fluid exits the platen. Of course, more inlets or outlets may be used. Advantageously, the sequence shown in FIG. 1 can be used to create cooling channels that are not confined to a single horizontal plane, as is typical with traditional ceramic platens. For example, the cooling channels may be disposed closer to the top surface of the platen in certain regions, such as along the outer edge. In other embodiments, the cooling channels may be disposed closer to the top surface of the platen near the center. The cooling channels may follow any desired pathway. For example, the cooling channels may be arranged in one or more planes. However, in certain embodiments, the cooling channels may be embedded in a non-planar configuration. Thus, the cooling channels may be disposed at a plurality of depths following a planar or non-planar pathway within the single piece ceramic platen. In certain embodiments, the sequence shown in FIG. 1 may also be used to create the back side gas channels that pass through the height of the platen and terminate at the top surface of the platen.

As described above, there may also be replacement regions in the platen, where the ceramic material is replaced with a different material. Although only two sequences are described herein, there are several techniques in which these replacement regions may be created, and the present disclosure is not limited to the sequences described herein.

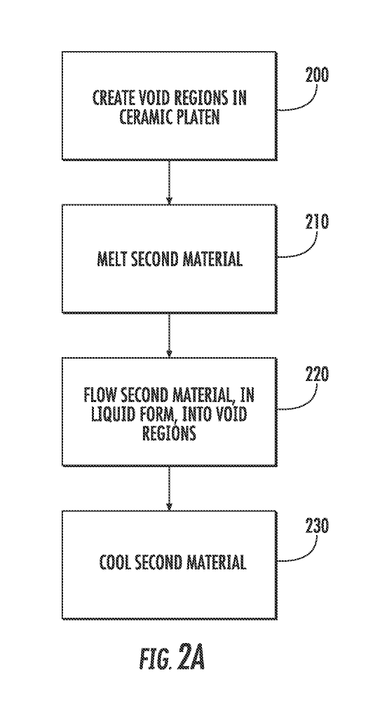

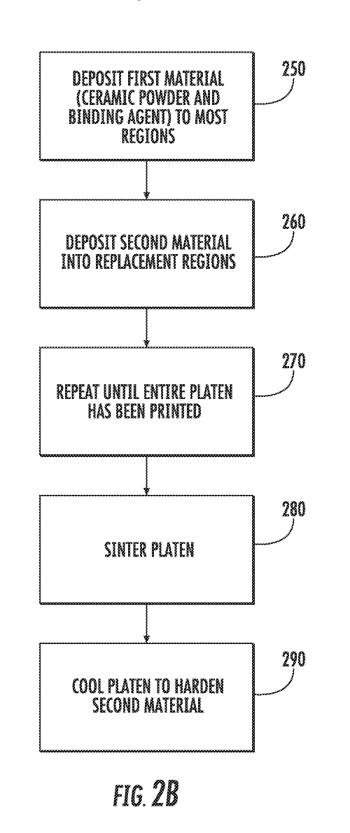

FIG. 2A shows a first sequence that may be used to create replacement regions in the ceramic platen. In this embodiment, void regions are created in those areas where the replacement regions are intended to exist, as shown in Process 200. The void regions may be created using the sequence shown in FIG. 1. After the platen is sintered, the void regions are then filled with a second material. For example, in some embodiments, the temperature of the environment is elevated so that the second material melts, as shown in Process 210. Once in liquid form, the second material can be flowed into the void regions of the platen, as shown in Process 220. When the second material cools, the void regions have been filled with the second material, effectively becoming replacement regions, as shown in Process 230. Although not shown, in another variation of this embodiment, the second material, which may be a metal, may be formed as a wire. This wire may be inserted into the void region prior to being melted. This process may be beneficial when the second material is intended to occupy only a portion of the void region.

FIG. 2B shows a second embodiment in which replacement regions may be created. In this embodiment, the additive manufacturing process is capable of depositing two different materials. In one embodiment, the first material, as described above, is a mixture of ceramic powder and binding agent, while the second material is a metallic powder. In another embodiment, the first material may be a ceramic slurry or paste while the second material may be a metallic ink or paste. As shown in Process 250, the first material is deposited in most regions, as this first material forms the ceramic material. The second material is deposited into the replacement regions, as shown in Process 260. This is repeated until the entire platen has been deposited, as shown in Process 270. After this, the platen is sintered, as shown in Process 280, which causes the first material to become hardened ceramic material. In certain embodiments, the platen is then cooled, as shown in Process 290, to allow the second material to solidify. This two material method can also be used to generate open channels for fluid or gas.

The replacement regions may be used to form embedded electrodes, heating elements, temperature sensors and other features.

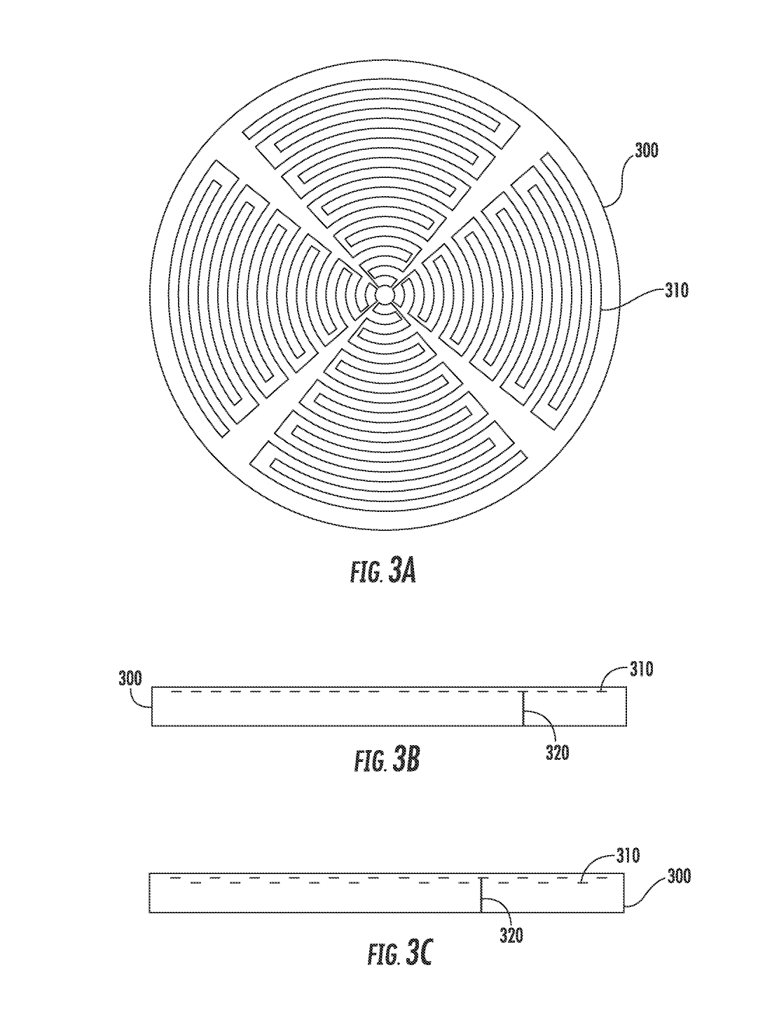

Through the use of void regions and replacement regions, a single piece ceramic platen may be created. FIG. 3A shows a top view of a single piece ceramic platen 300, having electrodes 310 embedded therein. Electrodes 310 are made of an electrically conductive material, such as a metal, and are embedded in the single piece ceramic platen 300 under the top surface. In some embodiments, there may be a plurality of electrodes 310 in the single piece ceramic platen 300. Each electrode 310 may have an electrical connection to a power supply, such as through the bottom surface of the single piece ceramic platen 300. These embedded electrodes 310 may be formed as a replacement region, as described in FIGS. 2A and 2B. If the replacement regions are formed using the sequence illustrated in FIG. 2A, the electrical connections through the bottom surface of the single piece ceramic platen 300 may serve as the entry point into which metal can be flowed or inserted.

FIG. 3B shows a side view of the single piece ceramic platen 300, where the electrodes 310 are disposed in a single horizontal plane. Electrical connection 320 may be used as the entry point for the metal, as described above. FIG. 3C shows a side view of the single piece ceramic platen 300, where the electrodes 310 are disposed at a plurality of depths. These electrodes 310 may follow a planar or non-planar pathway.

The additive manufacturing process described herein makes it possible to create embedded electrodes at a plurality of different depths, a feature that is extremely difficult to achieve use current manufacturing techniques.

Additionally, heating elements may be embedded in the single piece ceramic platen. Like the cooling channels, the heating elements may follow any desired pathway. For example, the heating elements may be arranged in one or more planes. However, in certain embodiments, the heating elements may be embedded in a non-planar configuration. Thus, like the cooling channels, the heating elements may also be disposed at a plurality of different depths following a planar or non-planar pathway within the single piece ceramic platen.

FIG. 4 shows a plurality of different elements that may be embedded using replacement regions. For example, in this embodiment, the single piece ceramic platen 400 includes embedded electrodes 410. As described above and shown in FIG. 4, these electrodes 410 may be disposed at a plurality of different depths and may follow a planar or non-planar pathway. In other embodiments, the electrodes 410 may be disposed in a single horizontal plane. As described above, the electrodes may be connected to a power supply through one or more electrode connections 411.

Additionally, heating elements 420 may be embedded in the single piece ceramic platen 400. The heating elements 420 may comprise a replacement region that is filled with a conductive material having a finite resistance, such as tungsten or copper. By flowing a current through the conductive material, heat is generated, which may be used to heat the single piece ceramic platen 400. The heating elements 420 are in communication with a heating power supply, which may connect to the heating elements 420 through an electrical connection 421 in the bottom surface of the single piece ceramic platen 400. If the replacement regions are created using the sequence shown in FIG. 2A, the electrical connection 421 may provide the inlet through which the second material is flowed into the single piece ceramic platen 400. As shown in FIG. 4, the heating elements 420 may be disposed at a plurality of different depths following a planar or non-planar pathway. For example, the heating elements 420 near the outer edge of the single piece ceramic platen 400 may be disposed closer to the top surface than the heating elements near the center. Of course, in other embodiments, the heating elements 420 may be arranged differently. In addition to controlling the position of the heating elements 420 within the platen, the additive manufacturing process allows other variations. For example, the cross-sectional area of the heating elements 420 may be varied throughout the single piece ceramic platen 400. For example, to modify the heating capabilities of various portions of the heating elements, the cross-sectional area may be varied as a function of distance from the center of the platen. In certain embodiments, the cross-sectional area may be varied by increasing its height (i.e. the dimension along the height of the platen, or Z direction). Additionally, the shape of the cross-section may also be modified if desired. Cross-sections of the heating elements 420 may be in the shape of a circle, ellipse, triangle, square, rectangle or any other suitable shape. This shape may also vary within the single piece ceramic platen 400.

In addition to heating elements 420 and electrodes 410, the additive manufacturing process allows the inclusion of other features. For example, in certain embodiments, one or more temperature sensors 430 may be embedded in the single piece ceramic platen 400. The temperature sensors 430 may include a temperature electrical connection 431 so that the temperature sensor 430 may be attached to a controller or other device. The temperature electrical connection 431 may exit through the bottom of the single piece ceramic platen 400, similar to the connections for the electrodes 410 and the heating elements 420. In certain embodiments, the temperature sensor 430 may be a thermocouple. In this embodiment, the temperature electrical connection 431 may include two outlets. Further, two different metals may be used to create the thermocouple. In certain embodiments, the two metals may be in the form of wires, which are each inserted into a respective outlet, and extended until they meet at a point inside the single piece ceramic platen. Once extended, the wires are then heated so that they melt together, forming a junction within the single piece ceramic platen 400. In the embodiment of FIG. 2B, the two different metals are deposited by the additive manufacturing process. Thus, a thermocouple may be formed as a replacement region, as described above. In another embodiment, the temperature sensor may be a resistance temperature detector (RTD). A RTD is a single wire which has a repeatable and measurable change in resistance as a function of temperature. This wire may be embedded in the single piece ceramic platen 400 in the same manner as the thermocouple.

Another feature that may be embedded is a strain gauge. As shown in FIG. 4, a strain gauge 440 is typically a wire that is arranged in a zig-zag pattern of parallel lines. Strain on the single piece ceramic platen 400 causes deflection of the wire in the strain gauge 440, which affects its resistance. This change in resistance is then measured and used to calculate the strain. While FIG. 4 shows the strain gauge 440 configured in the vertical direction, it is understood that the strain gauge may also be arranged in a horizontal direction or any other orientation. The strain gauge 440 may be embedded in a similar manner as the other embedded features. The strain gauge electrical connection 441 may exit through the bottom of the single piece ceramic platen 400, similar to the connections for the electrodes 410, the heating elements 420 and the temperature sensor 430.

Thus, through the use of additive manufacturing, a single piece ceramic platen having embedded features may be created. These features may be introduced using various processes, such as those shown in FIGS. 1, 2A and 2B.

In certain embodiments, the single piece ceramic platen includes electrodes embedded therein, where the electrodes are used to create an electrostatic force on the top surface of the single piece ceramic platen. In certain embodiments, the electrodes may be disposed in a single horizontal plane. In other embodiments, the electrodes may be disposed at a plurality of different depths. As described above, the electrodes may connect to an external power supply through electrical connections that exit the single piece ceramic platen through the bottom surface. Further, the number of electrodes that are embedded in the single piece ceramic platen is not limited by this disclosure.

In certain embodiments, the single piece ceramic platen includes heating elements embedded therein, where the heating elements are used to raise and maintain the temperature of the single piece ceramic platen. In certain embodiments, the heating elements may be disposed in a single horizontal plane. In other embodiments, the heating elements may be disposed at a plurality of different depths within the platen following a planar or non-planar pathway. As described above, the heating elements may connect to an external power supply through electrical connections that exit the single piece ceramic platen through the bottom surface. Additionally, the cross-sectional area of the heating elements may be modified using additive manufacturing processes. Further, the cross-sectional shape may also be modified, as desired. Further, the number of heating elements that are embedded in the single piece ceramic platen is not limited by this disclosure. Further, using the process described herein, it is possible to embed a plurality of separately controllable heating elements. For example, the heating elements disposed near the outer edge of the platen may form a first electrical circuit and the heating elements disposed near the center may form a second electrical circuit. These electrical circuits may be separately controllable, such that the current flowing through each circuit is independent of the other circuits. This may allow the platen to be maintained at a more uniform temperature.

Further, other features, such as temperature sensors and strain gauges, may also be embedded in the single piece ceramic platen.

In addition to the addition of features into the single piece ceramic platen, the present disclosure also discloses the creation of void regions within the single piece ceramic platen. These void regions may be used to create cooling channels, which carry a cooling fluid through the platen to reduce or maintain the temperature of the platen. Additionally, these void regions may be used to create back side gas channels, which deliver gas to the top surface of the single piece ceramic platen.

Further, any combination of the above features and void regions may be incorporated into one single piece ceramic platen. Thus, one single piece ceramic platen may comprise both heating elements and cooling channels. This combination may allow one single piece ceramic platen to be used for both hot implants and room temperature or cold implants.

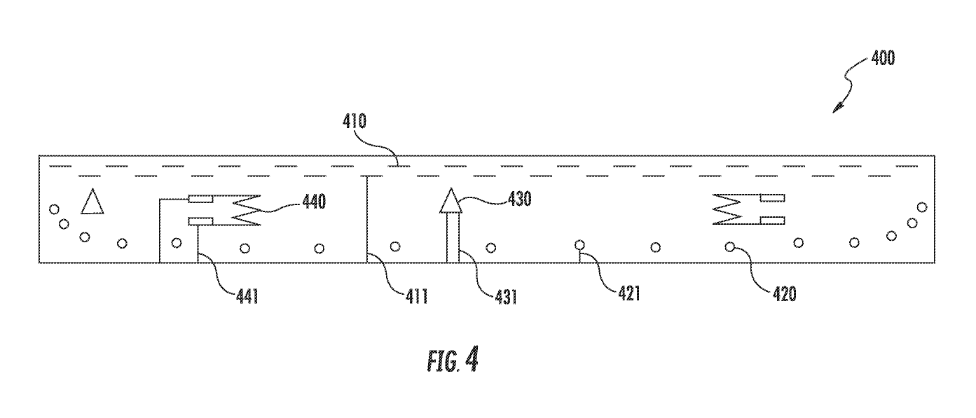

FIGS. 5A-5B show a single piece ceramic platen 500 having both heating elements 510 and cooling channels 520. As can be seen in FIG. 5A, the cooling channel 520 includes an inlet 521 and an outlet 522. The void region can be manufactured according to the sequence of FIG. 1 to create the cooling channel 520. The heating elements 510 also include at least two outlets 511, 512. As described earlier, the heating elements 510 may be created using the sequences shown in FIGS. 2A-2B. Further, FIGS. 5A-5B show the complexity that is possible using the additive manufacturing process. Specifically, the cooling channel 520 is disposed in the same single piece ceramic platen 500 as the heating elements 510. Further, as seen in FIG. 5B, the cooling channels 520 and heating elements 510 are disposed at a plurality of different depths following a planar or non-planar pathway within the single piece ceramic platen 500. Further, the cooling channels 520 and the heating elements 510 may be interweaved, such that the cooling channel 520 passes above the heating elements 510 at a first point 530, and passes below the heating element 510 at a second point 540. These configurations are not possible with traditional platens.

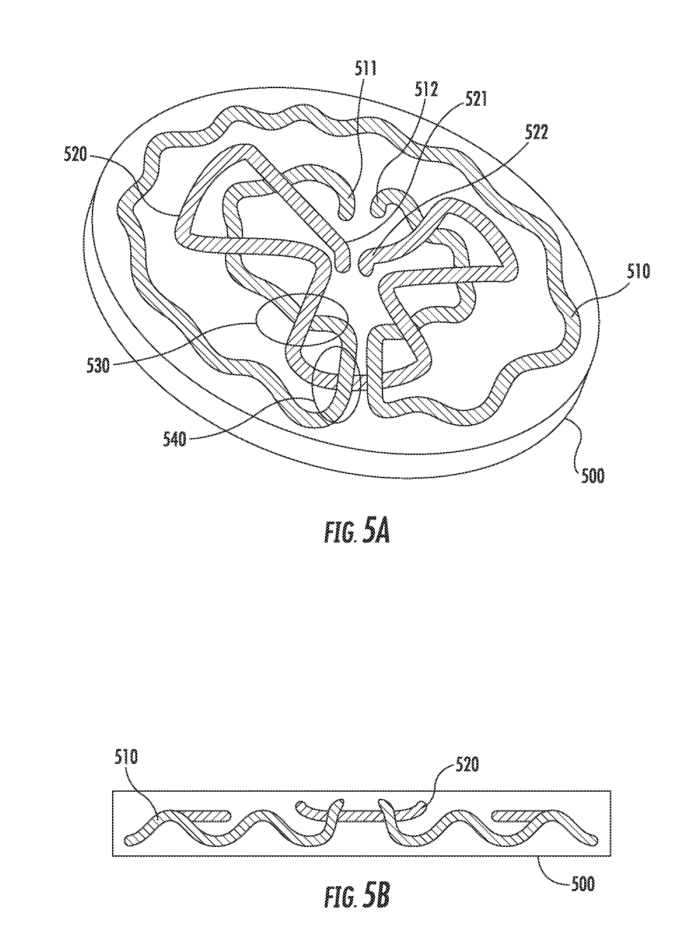

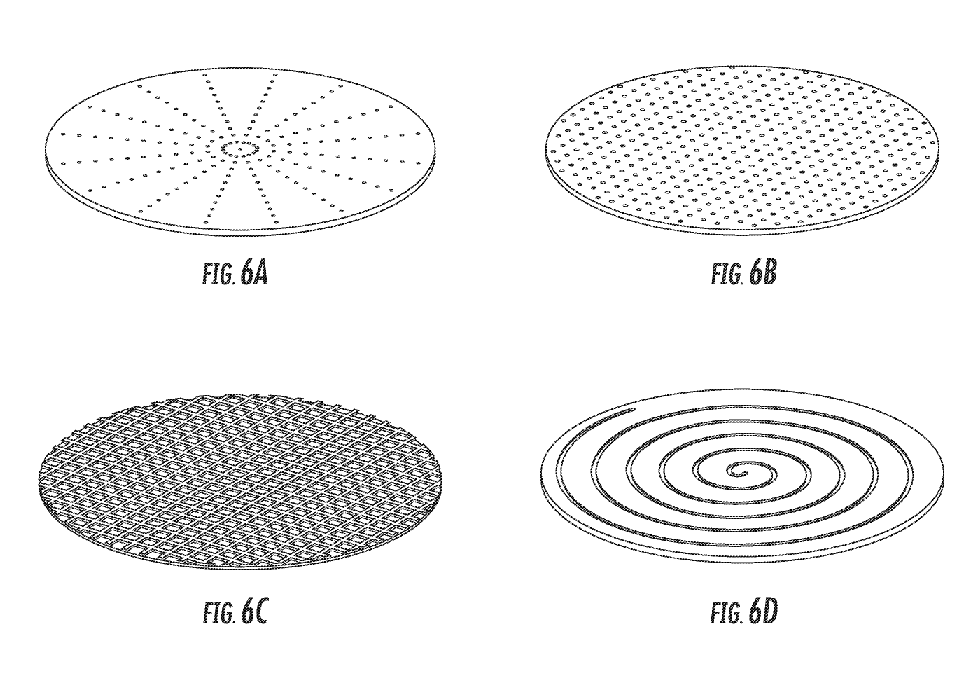

FIGS. 6A-6D shows a plurality of different top surface textures that may be applied to the single piece ceramic platen using the additive manufacturing techniques described herein. Textures such as waffles (see FIG. 6C), bumps (see FIGS. 6A and 6B), lines (see FIG. 6A), concentric circles, pyramids or spirals (see FIG. 6D) may be produced on the top surface of the single piece ceramic platen. These textures may be used to set back side gas gap, back side gas flow, or to change the heat transfers characteristics.

The embodiments described above in the present application may have many advantages. First, an additive manufacturing process may simplify the manufacturing process, allowing these platens to be sourced from multiple vendors. Second, the additive manufacturing process greatly simplifies the process of embedding features within the platen. This has several benefits. More features may be embedded into one platen. Additionally, these features may be more complex. For example, heating elements or electrodes may be disposed at a plurality of depths following a planar or non-planar pathway within the ceramic material. Third, this additive process allows the creation of platens that comprise both heating elements and cooling channels, allowing these platens to be used over a much wider range of temperatures. Further, additional functions, such as temperature sensors and strain gauges may also be embedded in these single piece ceramic platens. Finally, a single piece ceramic would be more structurally sound than conventional ceramic platens, which sinter multiple ceramic pieces together.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A platen, comprising:
a ceramic material;
a heating element embedded within the ceramic material; and
cooling channels passing through the ceramic material.

2. The platen of claim 1, further comprising electrodes embedded within the ceramic material.

3. The platen of claim 1, further comprising a temperature sensor embedded in the ceramic material.

4. The platen of claim 1, wherein the heating element and the cooling channels are interweaved.

5. The platen of claim 1, wherein the heating element is disposed at a plurality of depths following a planar or non-planar pathway within the ceramic material.

6. The platen of claim 1, wherein the cooling channels are disposed at a plurality of depths following a planar or non-planar pathway within the ceramic material.

7. A platen comprising:
a ceramic material; and
heating elements embedded within the ceramic material, wherein the heating elements are disposed at a plurality of different depths following a planar or non-planar pathway within the ceramic material.

8. The platen of claim 7, wherein heating elements near an outer edge of the platen are disposed closer to a top surface of the platen than heating elements near a center of the platen.

9. The platen of claim 7, wherein a cross-sectional area of the heating elements varies within the ceramic material.

10. The platen of claim 7, wherein a cross-sectional shape of the heating elements varies within the ceramic material.

11. The platen of claim 7, wherein the heating elements are configured as a plurality of separately controllable electrical circuits.

12. The platen of claim 7, further comprising electrodes embedded within the ceramic material.

13. The platen of claim 7, further comprising a temperature sensor embedded in the ceramic material.

14. The platen of claim 7, further comprising a strain gauge embedded in the ceramic material.

15. A platen comprising:
a ceramic material; and
cooling channels embedded within the ceramic material, wherein the cooling channels are disposed at a plurality of different depths following a planar or non-planar pathway within the ceramic material.

16. The platen of claim 15, wherein cooling channels near an outer edge of the platen are disposed closer to a top surface of the platen than cooling channels near a center of the platen.

17. The platen of claim 15, wherein cooling channels near an outer edge of the platen are disposed further from a top surface of the platen than cooling channels near a center of the platen.

18. The platen of claim 15, further comprising electrodes embedded within the ceramic material.

19. The platen of claim 15, further comprising a temperature sensor embedded in the ceramic material.

20. The platen of claim 15, further comprising a strain gauge embedded in the ceramic material.
